(19) United States
(12) Patent Application Publication
(10) Pub. No.: US 2010/0269896 A1
(43) Pub. Date: Oct. 28, 2010

(54) MICROCRYSTALLINE SILICON ALLOYS FOR THIN FILM AND WAFER BASED SOLAR APPLICATIONS

(75) Inventors: Shuran SHENG, Cupertino, CA (US); Yong Kee Chae, San Roman, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc., Santa Clara, CA (US)

(21) Appl. No.: 12/637,630

(22) Filed: Dec. 14, 2009

Related U.S. Application Data
(63) Continuation-in-part of application No. 12/208,478, filed on Sep. 11, 2008.
(60) Provisional application No. 61/139,390, filed on Dec. 19, 2008.

(51) Int. Cl. H01L 31/0288; H01L 31/02; B05C 11/00

(52) U.S. Cl. 136/255; 136/252; 118/696; 438/72; 257/E31.014

(57) ABSTRACT

A method and apparatus for forming solar cells is provided. Doped crystalline semiconductor alloys including carbon, oxygen, and nitrogen are used as light-trapping enhancement layers and charge collection layers for thin-film solar cells. The semiconductor alloy layers are formed by providing semiconductor source compound and a co-component source compound to a processing chamber and ionizing the gases to deposit a layer on a substrate. The alloy layers provide improved control of refractive index, wide optical bandgap and high conductivity.

### CROSS-REFERENCE TO RELATED APPLICATIONS

This application is a continuation-in-part of co-pending U.S. patent application Ser. No. 12/208,478 filed Sep. 11, 2008 (Attorney Docket No. APPM/13551), and claims benefit of U.S. provisional patent application Ser. No. 61/139,390, filed Dec. 19, 2008. Each of the aforementioned related patent applications are herein incorporated by reference in their entireties.

### BACKGROUND OF THE INVENTION

1. Field of the Invention

Embodiments of the present invention generally relate to solar cells and methods for forming the same. More particularly, embodiments of the present invention relate to a wavelength selective reflector layer formed in thin-film and crystalline solar cells.

2. Description of the Related Art

Crystalline silicon solar cells and thin film solar cells are two types of solar cells. Crystalline silicon solar cells typically use either mono-crystalline substrates (i.e., single-crystal substrates of pure silicon) or multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-n junctions. Suitable substrates include glass, metal, and polymer substrates.

To expand the economic uses of solar cells, efficiency must be improved. Solar cell efficiency relates to the proportion of incident radiation converted into useful electricity. To be useful for more applications, solar cell efficiency must be improved beyond the current best performance of approximately 15%. With energy costs rising, there is a need for improved thin film solar cells and methods and apparatuses for forming the same in a factory environment.

### SUMMARY OF THE INVENTION

Embodiments of the invention provide methods of forming solar cells. Some embodiments provide a method of making a solar cell, comprising forming a conductive layer on a substrate, and forming a p-type crystalline semiconductor alloy layer on the conductive layer. Some embodiments of the invention may also include amorphous or intrinsic semiconductor layers, n-type doped amorphous or crystalline layers, buffer layers, degeneratively doped layers, and conductive layers. A second conductive layer may be formed on an n-typed crystalline layer.

Alternate embodiments provide a method of forming a solar cell, comprising forming a conductive layer on a substrate, forming a first doped crystalline semiconductor alloy layer on the conductive layer, and forming a second doped crystalline semiconductor alloy layer over the first doped crystalline semiconductor alloy layer. Some embodiments may also include undoped amorphous or crystalline semiconductor layers, buffer layers, degeneratively doped layers, and conductive layers. Some embodiments may also include a third and fourth doped crystalline semiconductor alloy layers in a tandem-junction structure.

Further embodiments provide a method of forming a solar cell, comprising forming a reflective layer on a semiconductor substrate, and forming a crystalline junction over the reflective layer, wherein the reflective layer comprises one or more crystalline semiconductor alloy layers.

Embodiments of the invention may further provide photovoltaic device, comprising a reflector layer disposed between a first p-i-n junction and a second p-i-n junction, and having a plurality of apertures formed therein, wherein each of the plurality of apertures are formed by removing a portion of material from the reflector layer before the second p-i-n junction is formed over the reflector layer.

Embodiments of the invention may further provide a method of forming a solar cell device, comprising forming a first p-i-n junction on a surface of a substrate, forming an first reflector layer over the first p-i-n junction, wherein the first reflector layer selectively reflects light having a wavelength between about 550 nm and about 800 nm back to the first p-i-n junction, and forming a second p-i-n junction on the first reflector layer.

Embodiments of the invention may further provide an automated and integrated system for forming a solar cell, comprising a first deposition chamber that is adapted to deposit a p-type silicon-containing layer on a surface of a substrate, a second deposition chamber that is adapted to deposit an intrinsic type silicon-containing layer and an n-type silicon-containing layer on the surface of the substrate, a third deposition chamber that is adapted to deposit an n-type reflector layer on the surface of the substrate, a patterning chamber that is adapted to form a plurality of apertures in the n-type reflector layer, and an automated conveyor device that is adapted to transfer the substrate between the first deposition chamber, second deposition chamber, third deposition chamber and patterning chamber.

Embodiments of the invention may further provide an automated and integrated system for forming a solar cell, comprising a first cluster tool comprising at least one processing chamber that is adapted to deposit a p-type silicon-containing layer on a surface of a substrate, at least one processing chamber that is adapted to deposit a intrinsic type silicon-containing layer over the surface of the substrate, and at least one processing chamber that is adapted to deposit a intrinsic type silicon-containing layer over the surface of the substrate, and a second cluster tool comprising at least one processing chamber that is adapted to deposit an n-type reflector layer on a surface of the substrate, and an automated conveyor device that is adapted to transfer a substrate between the first and second cluster tools.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic side-view of a tandem junction thin-film solar cell having an wavelength selective reflector layer disposed between junctions according to one embodiment of the invention;

FIG. 2 is schematic side-view of a single junction thin-film solar cell according to one embodiment of the invention;

FIG. 3 is schematic side-view of a tandem junction thin-film solar cell having an wavelength selective reflector layer disposed between junctions according to one embodiment of the invention;

FIG. 4 is a schematic side-view of a tandem-junction thin-film solar cell according to another embodiment of the invention;

FIG. 5A-5B is a schematic side-view of a tandem junction thin-film solar cell having an wavelength selective reflector layer disposed between junctions according to one embodiment of the invention;

FIG. 6A-6B is a magnified view of an wavelength selective reflector layer disposed between junctions according to one embodiment of the invention;

FIG. 7 is a cross-sectional view of an apparatus according to one embodiment of the invention;

FIG. 8 is a plan view of an apparatus according to another embodiment of the invention; and

FIG. 9 is a plan view of a portion of a production line having apparatuses of FIGS. 7 and 8 incorporated therein according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Thin-film solar cells are generally formed from numerous types of films, or layers, put together in many different ways. Most films used in such devices incorporate a semiconductor element, that may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, and conductivity. Typically, most of these films can be formed by use of a chemical vapor deposition process, which may include some degree of ionization or plasma formation.

### Films Used in Solar Cells

Charge generation during a photovoltaic process is generally provided by a bulk semiconductor layer, such as a silicon containing layer. The bulk layer is also sometimes called an intrinsic layer to distinguish it from the various doped layers present in the solar cell. The intrinsic layer may have any desired degree of crystallinity, which will influence its light-absorbing characteristics. For example, an amorphous intrinsic layer, such as amorphous silicon, will generally absorb light at different wavelengths from intrinsic layers having different degrees of crystallinity, such as microcrystalline silicon. For this reason, most solar cells will use both types of layers to yield the broadest possible absorption characteristics. In some instances, an intrinsic layer may be used as a buffer layer between two dissimilar layer types to provide a smoother transition in optical or electrical properties between the two layers.

Silicon and other semiconductors can be formed into solids having varying degrees of crystallinity. Solids having essentially no crystallinity are amorphous, and silicon with negligible crystallinity is referred to as amorphous silicon. Completely crystalline silicon is referred to as crystalline, polycrystalline, or monocrystalline silicon. Polycrystalline silicon is crystalline silicon formed into numerous crystal grains separated by grain boundaries. Monocrystalline silicon is a single crystal of silicon. Solids having partial crystallinity, that is a crystal fraction between about 5% and about 95%, are referred to as nanocrystalline or microcrystalline, generally referring to the size of crystal grains suspended in an amorphous phase. Solids having larger crystal grains are referred to as microcrystalline, whereas those with smaller crystal grains are nanocrystalline. It should be noted that the term “crystalline silicon” may refer to any form of silicon having a crystal phase, including microcrystalline and nanocrystalline silicon.

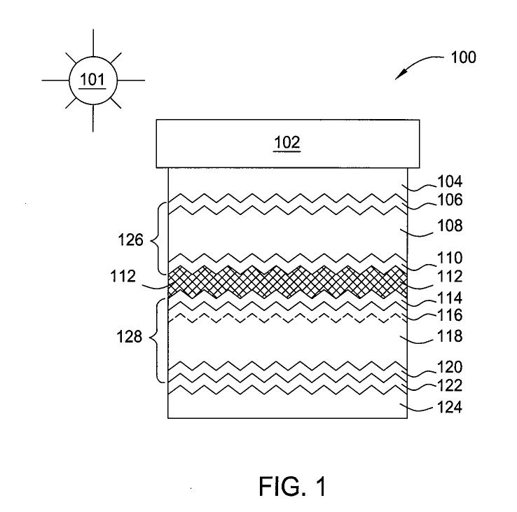

FIG. 1 is a schematic diagram of an embodiment of a multi-junction solar cell 100 oriented toward the light or solar radiation 101. Solar cell 100 comprises a substrate 102, such as a glass substrate, polymer substrate, metal substrate, or other suitable substrate, with thin films formed thereover. The solar cell 100 further comprises a first transparent conducting oxide (TCO) layer 104 formed over the substrate 102, a first p-i-n junction 126 formed over the first TCO layer 104. In one configuration, a wavelength selective reflector (WSR) layer 112 is formed over the first p-i-n junction 126. A second p-i-n junction 128 formed over the first p-i-n junction 126, a second TCO layer 122 formed over the second p-i-n junction 128, and a metal back layer 124 formed over the second TCO layer 122. In one embodiment, the WSR layer 112 is disposed between the first p-i-n junction 126 and the second p-i-n junction 128, and is configured to have film properties that improve light scattering and current generation in the formed solar cell 100. Additionally, the WSR layer 112 also provides a good p-n tunnel junction that has a high electrical conductivity and a tailored bandgap range that affect its transmissive and reflective properties to improve the formed solar cell's light conversion efficiency. Detail description of the WSR layer 112 will be further discussed below.

To improve light absorption by enhancing light trapping, the substrate and/or one or more of thin films formed thereover may be optionally textured by wet, plasma, ion, and/or mechanical processes. For example, in the embodiment shown in FIG. 1, the first TCO layer 104 is textured and the subsequent thin films deposited thereover will generally follow the topography of the surface below it.

The first TCO layer 104 and the second TCO layer 122 may each comprise tin oxide, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable dopants. Zinc oxide preferably comprises 5 atomic % or less of dopants, and more preferably comprises 2.5 atomic % or less aluminum. In certain instances, the substrate 102 may be provided by the glass manufacturers with the first TCO layer 104 already provided.

The first p-i-n junction 126 may comprise a p-type amorphous silicon layer 106, an intrinsic type amorphous silicon layer 108 formed over the p-type amorphous silicon layer 106, and an n-type microcrystalline silicon layer 110 formed over the intrinsic type amorphous silicon layer 124. In certain embodiments, the p-type amorphous silicon layer 106 may be formed to a thickness between about 60 Å and about 300 Å. In certain embodiments, the intrinsic type amorphous silicon layer 108 may be formed to a thickness between about 1,500 Å and about 3,500 Å. In certain embodiments, the n-type microcrystalline semiconductor layer 110 may be formed to a thickness between about 100 Å and about 400 Å.

The WSR layer 112 disposed between the first p-i-n junction 126 and the second p-i-n junction 128 is generally configured to have certain desired film properties. In this configuration the WSR layer 112 actively serves as an intermediate reflector having a desired refractive index, or ranges of refractive indexes, to reflect light received from the light incident side of the solar cell 100. The WSR layer 112 also serves as a junction layer that boosts the absorption of the short to mid wavelengths of light (e.g., 280 nm to 800 nm) in the first p-i-n junction 126 and improves short-circuit current, resulting in improved quantum and conversion efficiency. The WSR layer 112 further has high film transmittance for mid to long wavelengths of light (e.g., 500 nm to 1100 nm) to facilitate the transmission of light to the layers formed in the junction 128. Further, it is generally desirable for the WSR layer 112 to absorb as little light as possible while reflecting desirable wavelengths of light (e.g., shorter wavelengths) back to the layers in the first p-i-n junction 126 and transmitting desirable wavelengths of light (e.g., longer wavelengths) to the layers in the second p-i-n junction 128. Additionally, the WSR layer 112 can have a desirable bandgap and high film conductivity so as to efficiently conduct the generated current and allow electrons to flow from the first p-i-n junction 126 to the second p-i-n junction 128, and avoid blocking the generated current. The WSR layer 112 is desired to reflect shorter wavelength light back to the first p-i-n junction 126 while allowing substantially all of the longer wavelengths of light to pass to second p-i-n junction 128. By forming a WSR layer 112 that has a high film transmittance of desired wavelengths, a low film light absorption, desirable band gap properties (e.g., wide band gap range), and a high electrical conductivity the overall solar cell conversion efficiency may be improved.

In one embodiment, the WSR layer 112 may be a microcrystalline silicon layer having n-type or p-type dopants disposed within the WSR layer 112. In an exemplary embodiment, the WSR layer 112 is an n-type crystalline silicon alloy having n-type dopants disposed within the WSR layer 112. Different dopants disposed within the WSR layer 112 may also influence the WSR layer film optical and electrical properties, such as bandgap, crystalline fraction, conductivity, transparency, film refractive index, extinction coefficient, and the like. In some instances, one or more dopants may be doped into various regions of the WSR layer 112 to efficiently control and adjust the film bandgap, work function(s), conductivity, transparency and so on. In one embodiment, the WSR layer 112 is controlled to have a refractive index between about 1.4 and about 4, a bandgap of at least about 2 eV, and a conductivity greater than about 0.3 S/cm.

In one embodiment, the WSR layer 112 may comprise an n-type doped silicon alloy layer, such as silicon oxide (SiOₓ, SiO₂), silicon carbide (SiC), silicon oxynitride (SiON), silicon nitride (SiN), silicon carbon nitride (SiCN), silicon oxycarbide (SiOC), silicon oxycarbon nitride (SiOCN), or the like. In an exemplary embodiment, the WSR layer 112 is an n-type SiON or SiC layer.

The second p-i-n junction 128 may comprise a p-type microcrystalline silicon layer 114, and in some cases an optional p-i buffer type intrinsic amorphous silicon (PIB) layer 116 that is formed over the p-type microcrystalline silicon layer 114. Subsequently, an intrinsic type microcrystalline silicon layer 118 is formed over the p-type microcrystalline silicon layer 114, and an n-type amorphous silicon layer 120 formed over the intrinsic type microcrystalline silicon layer 118. In certain embodiments, the p-type microcrystalline silicon layer 114 may be formed to a thickness between about 100 Å and about 400 Å. In certain embodiments, the p-i buffer type intrinsic amorphous silicon (PIB) layer 116 may be formed to a thickness between about 50 Å and about 500 Å. In certain embodiments, the intrinsic type microcrystalline silicon layer 118 may be formed to a thickness between about 10,000 Å and about 30,000 Å. In certain embodiments, the n-type amorphous silicon layer 120 may be formed to a thickness between about 100 Å and about 500 Å.

The metal back layer 124 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 124 to complete the solar cell device. The formed solar cells may be interconnected to form modules, which in turn can be connected to form arrays.

Solar radiation 101 is primarily absorbed by the intrinsic layers 108, 118 of the p-i-n junctions 126, 128 and is converted to electron-holes pairs. The electric field created between the p-type layer 106, 114 and the n-type layer 110, 120 that stretches across the intrinsic layer 108, 118 causes electrons to flow toward the n-type layers 110, 120 and holes to flow toward the p-type layers 106, 114 creating a current. The first p-i-n junction 126 comprises an intrinsic type amorphous silicon layer 108 and the second p-i-n junction 128 comprises an intrinsic type microcrystalline silicon layer 118 since amorphous silicon and microcrystalline silicon absorb different wavelengths of the solar radiation 101. Therefore, the formed solar cell 100 is more efficient, since it captures a larger portion of the solar radiation spectrum. The intrinsic layer 108, 118 of amorphous silicon and the intrinsic layer of microcrystalline are stacked in such a way that solar radiation 101 first strikes the intrinsic type amorphous silicon layer 118 and transmitted through the WSR layer 112 and then strikes the intrinsic type microcrystalline silicon layer 118 since amorphous silicon has a larger bandgap than microcrystalline silicon. Solar radiation not absorbed by the first p-i-n junction 126 continuously transmits through the WSR layer 112 and continues on to the second p-i-n junction 128.

The intrinsic amorphous silicon layer 108 may be deposited by providing a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. An RF power between 15 mW/cm² and about 250 mW/cm² may be provided to the showerhead. The pressure of the chamber may be maintained between about 0.1 Torr and 20 Torr, such as between about 0.5 Torr and about 5 Torr. The deposition rate of the intrinsic type amorphous silicon layer 108 will be about 100 Å/min or more. In an exemplary embodiment, the intrinsic type amorphous silicon layer 108 is deposited at a hydrogen to silane ratio at about 12.5:1.

The p-i buffer type intrinsic amorphous silicon (PIB) layer 116 may be deposited by providing a gas mixture of hydrogen gas to silane gas in a ratio of about 50:1 or less, for example, less than about 30:1, for example between about 20:1 and about 30:1, such as about 25:1. Silane gas may be provided at a flow rate between about 0.5 sccm/L and about 5 sccm/L, such as about 2.3 sccm/L. Hydrogen gas may be provided at a flow rate between about 5 sccm/L and 80 sccm/L, such as between about 20 sccm/L and about 65 sccm/L, for example about 57 sccm/L. An RF power between 15 mW/cm² and about 250 mW/cm², such as between about 30 mW/cm² may be provided to the showerhead. The pressure of the chamber may be maintained between about 0.1 Torr and 20 Torr, preferably between about 0.5 Torr and about 5 Torr, such as about 3 Torr. The deposition rate of the PIB layer will be about 100 Å/min or more.

The intrinsic type microcrystalline silicon layer 118 may be deposited by providing a gas mixture of silane gas and hydrogen gas in a ratio of hydrogen to silane between about 20:1 and about 200:1. Silane gas may be provided at a flow rate between about 0.5 sccm/L and about 5 sccm/L. Hydrogen gas may be provided at a flow rate between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. Applying RF power between about 300 mW/cm² or greater, preferably 600 mW/cm² or greater, at a chamber pressure between about 1 Torr and about 100 Torr, preferably between about 3 Torr and about 20 Torr, more preferably between about 4 Torr and about 12 Torr, will generally deposit an intrinsic type microcrystalline silicon layer having crystalline fraction between about 20 percent and about 80 percent, preferably between 55 percent and about 75 percent, at a rate of about 200 Å/min or more, preferably about 500 Å/min. In some embodiments, it may be advantageous to ramp the power density of the applied RF power from a first power density to a second power density during deposition.

In another embodiment, the intrinsic type microcrystalline silicon layer 118 may be deposited in multiple steps, each having different crystal fraction. In one embodiment, for example, the ratio of hydrogen to silane may be reduced in four steps from 100:1 to 95:1 to 90:1 and then to 85:1. In one embodiment, silane gas may be provided at a flow rate between about 0.1 sccm/L and about 5 sccm/L, such as about 0.97 sccm/L. Hydrogen gas may be provided at a flow rate between about 10 sccm/L and about 200 sccm/L, such as between about 80 sccm/L and about 105 sccm/L. In an exemplary embodiment wherein the deposition has multiple steps, such as four steps, the hydrogen gas flow may start at about 97 sccm/L in the first step, and be gradually reduced to about 92 sccm/L, 88 sccm/L, and 83 sccm/L respectively in the subsequent process steps. Applying RF power between about 300 mW/cm² or greater, such as about 490 mW/cm² at a chamber pressure between about 1 Torr and about 100 Torr, for example between about 3 Torr and about 20 Torr, such as between about 4 Torr and about 12 Torr, such as about 9 Torr, will result in deposition of an intrinsic type microcrystalline silicon layer at a rate of about 200 Å/min or more, such as 400 Å/min.

Charge collection is generally provided by doped semiconductor layers, such as silicon layers doped with p-type or n-type dopants. P-type dopants are generally group III elements, such as boron or aluminum. N-type dopants are generally group V elements, such as phosphorus, arsenic, or antimony. In most embodiments, boron is used as the p-type dopant and phosphorus as the n-type dopant. These dopants may be added to the p-type and n-type layers 106, 110, 114, 120 described above by including boron-containing or phosphorus-containing compounds in the reaction mixture. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF), and triethylboron (B(C₂H₅)₃ or TEB). Phosphine is the most common phosphorus compound. The dopants are generally provided with carrier gases, such as hydrogen, helium, argon, and other suitable gases. If hydrogen is used as the carrier gas, it adds to the total hydrogen in the reaction mixture. Thus hydrogen ratios will include hydrogen used as a carrier gas for dopants.

Dopants will generally be provided as dilute gas mixtures in an inert gas. For example, dopants may be provided at molar or volume concentrations of about 0.5% in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, dopant concentration is maintained between about 10¹⁸ atoms/cm² and about 10²⁰ atoms/cm².

In one embodiment, the p-type microcrystalline silicon layer 114 may be deposited by providing a gas mixture of hydrogen gas and silane gas in ratio of hydrogen-to-silane of about 200:1 or greater, such as 1000:1 or less, for example between about 250:1 and about 800:1, and in a further example about 601:1 or about 401:1. Silane gas may be provided at a flow rate between about 0.1 sccm/L and about 0.8 sccm/L, such as between about 0.2 sccm/L and about 0.38 sccm/L. Hydrogen gas may be provided at a flow rate between about 60 sccm/L and about 500 sccm/L, such as about 143 sccm/L. TMB may be provided at a flow rate between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. Applying RF power between about 50 mW/cm² and about 700 mW/cm², such as between about 290 mW/cm² and about 440 mW/cm², at a chamber pressure between about 1 Torr and about 100 Torr, preferably between about 3 Torr and about 20 Torr, more preferably between 4 Torr and about 12 Torr, such as about 7 Torr or about 9 Torr, will deposit a p-type microcrystalline layer having crystalline fraction between about 20 percent and about 80 percent, preferably between 50 percent and about 70 percent for a microcrystalline layer, at about 10 Å/min or more, such as about 143 Å/min or more.

In one embodiment, the p-type amorphous silicon layer 106 may be deposited by providing a gas mixture of hydrogen gas to silane gas in a ratio of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. Applying RF power between about 15 mWatts/cm² and about 200 mWatts/cm² at a chamber pressure between about 0.1 Torr and 20 Torr, preferably between about 1 Torr and about 4 Torr, will deposit a p-type amorphous silicon layer at about 100 Å/min or more.

In on embodiment, the n-type microcrystalline silicon layer 110 may be deposited by providing a gas mixture of hydrogen gas to silane gas in a ratio of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. Applying RF power between about 100 mW/cm² and about 900 mW/cm², such as about 370 mW/cm², at a chamber pressure of between about 1 Torr and about 100 Torr, preferably between about 3 Torr and about 20 Torr, more preferably between 4 Torr and about 12 Torr, for example about 6 Torr or about 9 Torr, will deposit an n-type microcrystalline silicon layer having a crystalline fraction between about 20 percent and about 80 percent, preferably between 50 percent and about 70 percent, at a rate of about 50 Å/min or more, such as about 150 Å/min or more.

In one embodiment, the n-type amorphous silicon layer 120 may be deposited by providing a gas mixture of hydrogen gas to silane gas in a ratio of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. Applying RF power between about 25 mW/cm² and about 250 mW/cm², such as about 60 mW/cm² or about 80 mW/cm², at a chamber pressure between about 0.1 Torr and about 20 Torr, preferably between about 0.5 Torr and about 4 Torr, such as about 1.5 Torr, will deposit an n-type amorphous silicon layer at a rate of about 100 Å/min or more, such as about 200 Å/min or more, such as about 300 Å/min or about 600 Å/min.

In some embodiments, layers may be heavily doped or degenerately doped by supplying dopant compounds at high rates, for example at rates in the upper part of the recipes described above. It is thought that degenerate doping improves charge collection by providing low-resistance contact junctions. Degenerate doping is also thought to improve conductivity of some layers, such as amorphous layers.

In some embodiments, alloys of silicon with other elements such as oxygen, carbon, nitrogen, hydrogen, and germanium may be useful. These other elements may be added to silicon films by supplementing the reactant gas mixture with sources of each. Alloys of silicon may be used in any type of silicon layers, including p-type, n-type, PIB, WSR layer, or intrinsic type silicon layers. For example, carbon may be added to the silicon films by adding a carbon source such as methane (CH₄) to the gas mixture. In general, most C₁-C₄ hydrocarbons may be used as carbon sources. Alternately, organosilicon compounds known to the art, such as organosilanes, organosiloxanes, organosilanols, and the like may serve as both silicon and carbon sources. Germanium compounds such as germanes and organogermanes, along with compounds comprising silicon and germanium, such as silylgermanes or germylsilanes, may serve as germanium sources. Oxygen gas (O₂) may serve as an oxygen source. Other oxygen sources include, but are not limited to, oxides of nitrogen (nitrous oxide —N₂O, nitric oxide —NO, dinitrogen trioxide —N₂O₃, nitrogen dioxide —NO₂, dinitrogen tetroxide —N₂O₄, dinitrogen pentoxide —N₂O₅, and nitrogen trioxide —NO₃), hydrogen peroxide (H₂O₂), carbon monoxide or dioxide (CO or CO₂), ozone (O₃), oxygen atoms, oxygen radicals, and alcohols (ROH, where R is any organic or hetero-organic radical group). Nitrogen sources may include nitrogen gas (N₂), ammonia (NH₃), hydrazine (N₂H₂), amines (RₓNR′₃₋ₓ, where x is 0 to 3, and each R and R′ is independently any organic or hetero-organic radical group), amides ((RCO)ₓNR′₃₋ₓ, where x is 0 to 3 and each R and R′ is independently any organic or hetero-organic radical group), imides (RCONCOR′, where each R and R′ is independently any organic or hetero-organic radical group), enamines (R₁R₂C═C₃NR₄R₅, where each R₁-R₅ is independently any organic or hetero-organic radical group), and nitrogen atoms and radicals.

It should be noted that in many embodiments pre-clean processes may be used to prepare substrates and/or reaction chambers for deposition of the above layers. A hydrogen or argon plasma pre-treat process may be performed to remove contaminants from substrates and/or chamber walls by supplying hydrogen gas or argon gas to the processing chamber between about 10 sccm/L and about 45 sccm/L, such as between about 15 sccm/L and about 40 sccm/L, for example about 20 sccm/L and about 36 sccm/L. In one example, the hydrogen gas may be supplied at about 21 sccm/L or the argon gas may be supplied at about 36 sccm/L. The treatment is accomplished by applying RF power between about 10 mW/cm² and about 250 mW/cm², such as between about 25 mW/cm² and about 250 mW/cm², for example about 60 mW/cm² or about 80 mW/cm² for hydrogen treatment and about 25 mW/cm² for argon treatment. In many embodiments it may be advantageous to perform an argon plasma pre-treatment process prior to depositing a p-type amorphous silicon layer, and a hydrogen plasma pre-treatment process prior to depositing other types of layers.

In one embodiment, the WSR layer 112 is an n-type crystalline silicon alloy layer formed over the n-type microcrystalline silicon layer 110. The n-type crystalline silicon alloy layer of the WSR layer 112 may be microcrystalline, nanocrystalline, or polycrystalline. The n-type crystalline silicon alloy WSR layer 112 may contain alloying elements, such as carbon, oxygen, nitrogen, or any combination thereof. It may be deposited as a single homogeneous layer, a single layer with one or more graduated characteristics, or as a stack of layers. The graduated characteristics may include crystallinity, dopant concentration (e.g., phosphorous), alloy material (e.g., carbon, oxygen, nitrogen) concentration, or other characteristics such as dielectric constant, refractive index, conductivity, or bandgap. The n-type crystalline silicon alloy WSR layer 112 may be contain an n-type silicon carbide layer, an n-type silicon oxide layer, an n-type silicon nitride layer, and n-type silicon oxynitride layer, an n-type silicon oxycarbide layer, and/or an n-type silicon oxycarbonitride layer.

The quantities of secondary components in the n-type crystalline silicon alloy WSR layer 112 may deviate from stoichiometric ratios to some degree. For example, an n-type silicon carbide layer may have between about 1 atomic % and about 50 atomic % carbon. An n-type silicon nitride layer may likewise have between about 1 atomic % and about 50 atomic % nitrogen. An n-type silicon oxide layer may have between about 1 atomic % and about 50 atomic % oxygen. In an alloy comprising more than one secondary component, the content of secondary components may be between about 1 atomic % and about 50 atomic %, with silicon content between 50 atomic % and 99 atomic %. The quantity of secondary components may be adjusted by adjusting the ratios of precursor gases in the processing chamber. The ratios may be adjusted in steps to form layered structures, or continuously to form graduated single layers.

Carbon containing gas, such as methane (CH₄), may be added to the reaction mixture for the n-type microcrystalline silicon layer to form an n-type microcrystalline silicon carbide WSR layer 112. In one embodiment, the ratio of carbon containing gas flow rate to silane flow rate is between about 0 and about 0.5, such as between about 0.20 and about 0.35, for example about 0.25. The ratio of carbon containing gas to silane in the feed may be varied to adjust the amount of carbon in the deposited film. The WSR layer 112 may be deposited in a number of layers, each having different carbon content, or the carbon content may be continuously adjusted through the deposited WSR layer 112. Moreover, the carbon and dopant content may be adjusted and graduated simultaneously within the WSR layer 112. Depositing the WSR layer 112 as a number of stacked layers has advantages in that each of the formed multiple layers can have a different refractive index that allows the multiple layer stack to operate as a Bragg reflector, significantly enhancing the reflectivity of the WSR layer 112 over a desired range of wavelengths, such as short to mid wavelengths.

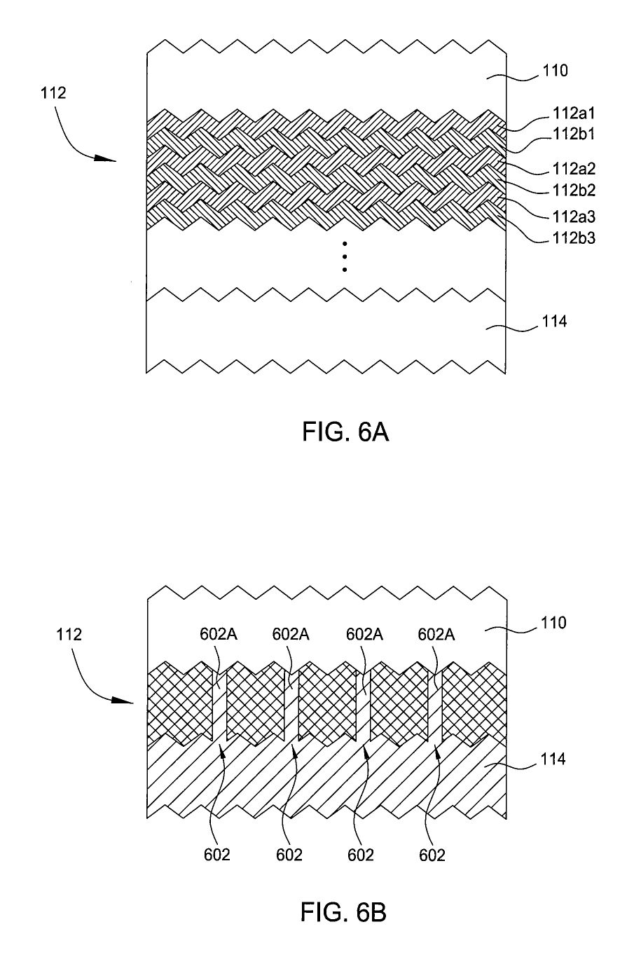

As discussed above, the n-type crystalline silicon alloy WSR layer 112 can provide several advantages. For example, the n-type crystalline silicon alloy WSR layer 112 can be positioned within at least three positions within a solar cell, such as act as a semi-reflective intermediate reflector layer, a second WSR reflector (e.g., reference numeral 512 in FIG. 6B) or act as a junction layer. Inclusion of the n-type crystalline silicon alloy WSR layer 112 as a junction layer boosts absorption of short wavelength light by the first p-i-n junction 126 and improves short-circuit current, resulting in improved quantum and conversion efficiency. Furthermore, the n-type crystalline silicon alloy WSR layer 112 has desired optical and electrical film properties, such as high conductivity, bandgap and refractive index for desired reflectance and transmittance. Microcrystalline silicon carbide, for example, develops crystalline fraction above 60%, bandgap width above 2 electron-volts (eV), and conductivity greater than 0.01 Siemens per centimeter (S/cm). Moreover, it can be deposited at rates of 150-200 Å/min or higher with thickness variation less than 10%. The bandgap and refractive index can be adjusted by varying the ratio of carbon containing gas to silane in the reaction mixture. The adjustable refractive index allows formation of a reflective layer that is highly conductive and has a wide bandgap, resulting in an improved generated current.

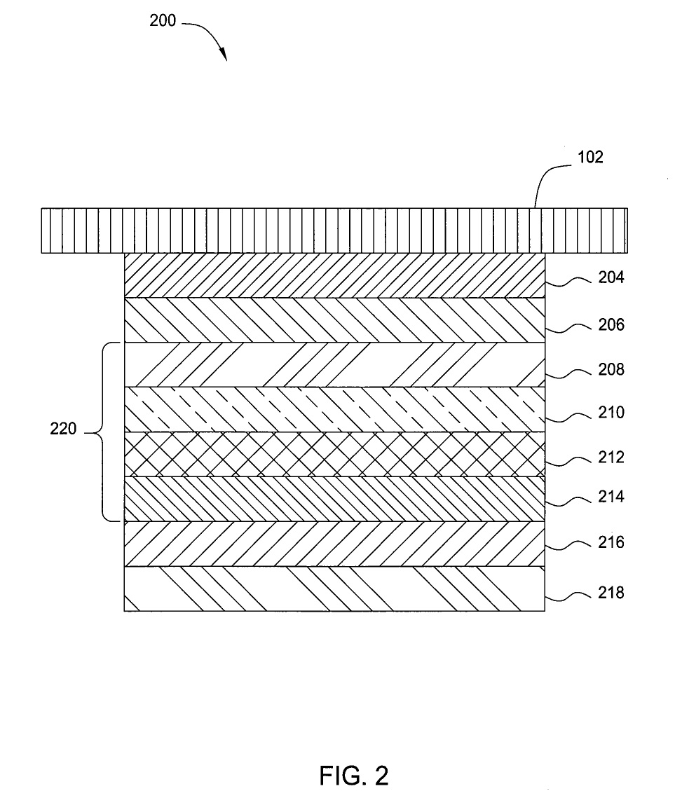

FIG. 2 is a schematic side-view of a single-junction thin-film solar cell 200 according to another embodiment of the invention. The embodiment of FIG. 2 differs from that of FIG. 1 by inclusion of a p-type crystalline silicon alloy layer 206 between the p-type amorphous silicon layer 106 and the first TCO layer 104 of FIG. 1. Alternatively, the p-type crystalline silicon alloy layer 206 may be a degeneratively doped layer having p-type dopants heavily doped in the alloy layer 206. The embodiment of FIG. 2 thus comprises the substrate 201 on which a conductive layer 204, such as a TCO layer similar to the first TCO layer 104 of FIG. 1, is formed. As described above, a p-type crystalline silicon alloy layer 206 is formed over the conductive layer 204. The p-type crystalline silicon alloy layer 206 has improved bandgap due to lower doping, adjustable refractive index generally lower than that of a degeneratively doped layer, high conductivity, and resistance to oxygen attack by virtue of the included alloy components. A p-i-n junction 220 is formed over the p-type crystalline silicon alloy layer 206 by forming a p-type amorphous silicon layer 208, a PIB layer 210, an intrinsic amorphous silicon layer 212, and an n-type amorphous silicon layer 214. The solar cell 200 of FIG. 2 is completed, similar to the foregoing embodiments, with an n-type crystalline silicon alloy layer 216, which is similar to the WSR layer 112 of FIG. 1, and a second conductive layer 218, which may be a metal or metal/TCO stack, similar to the conductive layers 122, 124 of FIG. 1.

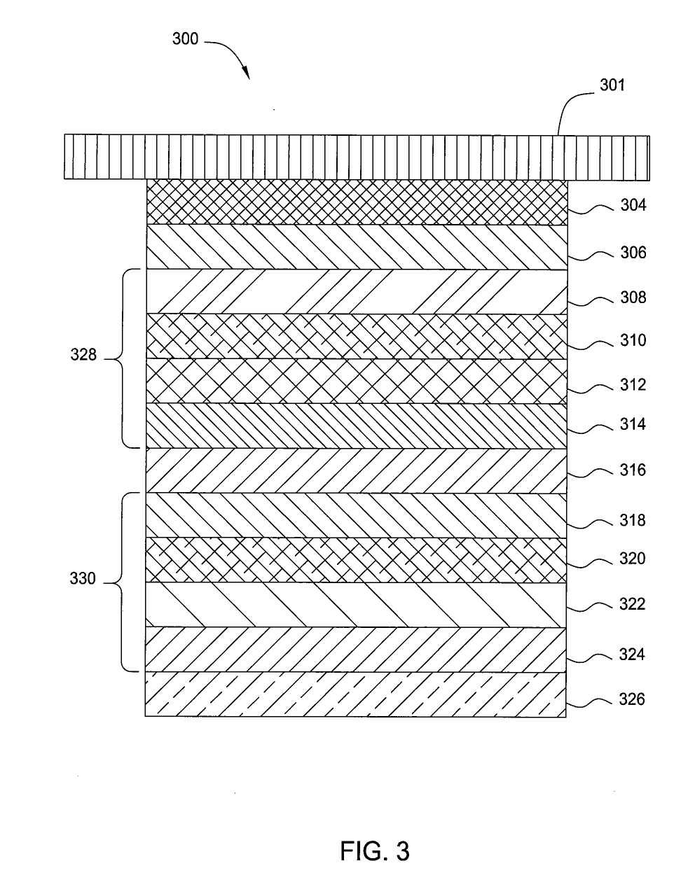

FIG. 3 is a schematic side-view of a tandem-junction thin-film solar cell 300 according to another embodiment of the invention. The embodiment of FIG. 3 differs from that of FIG. 1 by inclusion of a first p-type crystalline silicon alloy layer 306 between a first conductive layer 304 and the p-type amorphous silicon alloy layer 308. Alternatively, the first p-type crystalline silicon alloy layer 306 may also be a degenerative-doped p-type amorphous silicon layer having p-type dopants disposed within the formed amorphous silicon layer. In one embodiment, as shown in FIG. 3, a substrate 301 similar to the substrates of the foregoing embodiments, comprises a conductive layer 304, a first p-type crystalline silicon alloy layer 306, a p-type amorphous silicon alloy layer 308, and a first PIB layer 310 formed thereover. The first PIB layer 310 may be optionally formed. In one example, the first p-i-n junction 328 of the tandem-junction thin-film solar cell 300 is completed by forming an intrinsic amorphous silicon layer 312, an n-type amorphous silicon layer 314 over the conductive layer 304, a first p-type crystalline silicon alloy layer 306, and a p-type amorphous silicon alloy layer 308. An WSR layer 316 may be formed between the first p-i-n junction 328 and a second p-i-n junction 330. The second p-i-n junction 330 is then formed over the WSR layer 316 having a second p-type crystalline silicon alloy layer 318, a second PIB layer 320, an intrinsic crystalline silicon layer 322, and a second n-type crystalline silicon alloy layer 324. The second p-i-n junction is similar to the second p-i-n junction 128 of the solar cell 100 of FIG. 1. Similar to the WSR layer 112 described in FIG. 1, the WSR layer 316 may be a n-type crystalline silicon alloy that is formed over the first p-i-n junction 328. The solar cell 300 is completed by adding a second contact layer 326 over the second n-type crystalline silicon alloy layer 324. As described above, the second contact layer 326 may be a metal layer or a metal/TCO stack layer.

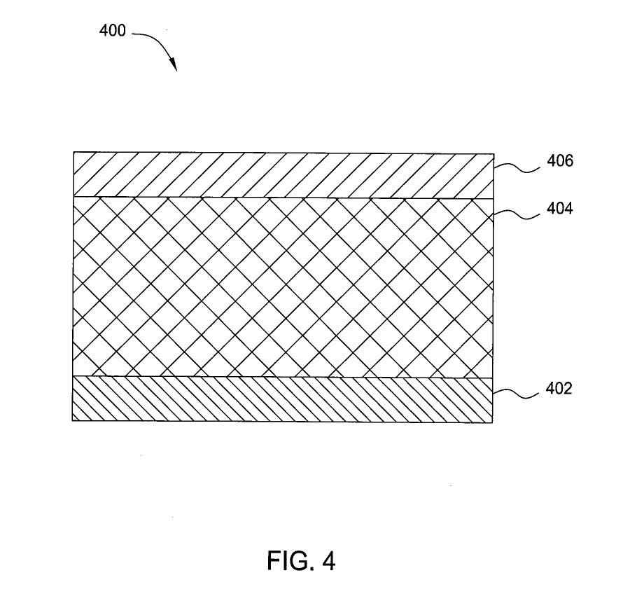

FIG. 4 is a schematic side-view of a crystalline solar cell 400 according to another embodiment of the invention. The embodiment of FIG. 4 comprises a semiconductor substrate 402, on which a crystalline silicon alloy layer 404 is formed. The crystalline silicon alloy layer 404 may be formed according to any of the embodiments and recipes disclosed herein, and may be a single alloy layer or a multi-layer stack of alloy layers. The crystalline silicon alloy layer 404 has adjustable low refractive index, as discussed above, and may be structured to enhance reflectivity, allowing the crystalline silicon alloy layer 404 to serve as a back reflector layer for the crystalline solar cell 406 formed thereon. In the embodiment of FIG. 4, the crystalline silicon alloy layer 404 may be formed to any convenient thickness, depending on the structure of the layer. A single layer embodiment may have a thickness between about 500 Å and about 5,000 Å, such as between about 1,000 Å and about 2,000 Å, for example about 1,500 Å. A multi-layer structure may feature a plurality of layers, each having a thickness between about 100 Å and about 1,000 Å.

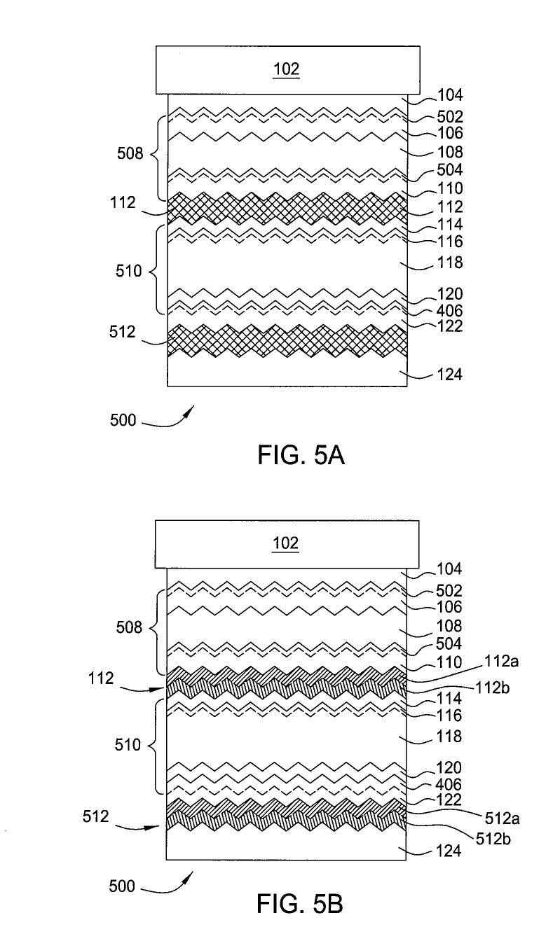

FIG. 5A is a schematic side-view of a tandem-junction thin-film solar cell 500 according to another embodiment of the invention. The embodiment of FIG. 5 has similar structures of FIG. 1, having the first TCO layer 104 disposed on the substrate 102 and two formed p-i-n junctions 508, 510. The WSR layer 112 is disposed between the first p-i-n junction 508 and the second p-i-n junctions 510. In one embodiment, the WSR layer 112 may be an n-type doped silicon alloy layer, such as SiO₂, SiC, SiON, SiN, SiCN, SiOC, SiOCN or the like. In an exemplary embodiment, the WSR layer 112 is an n-type SiON or SiC layer.

Additionally, a second WSR layer 512, (e.g. or called as a back reflector layer), may also be disposed between the second p-i-n junction 510 and the second TCO layer 122 or the metal back layer 124. The second WSR layer 512 may have similar film properties as the first WSR layer 112, which is discussed above. Just as the first WSR layer 112 desirably reflects short wavelengths of light back to the first p-i-n junction 508 and allows long wavelengths of light to pass to the second p-i-n cell 510, the second WSR layer 512 is configured to reflect the long wavelengths of light back to the second p-i-n junction 510 and have a low electrically resistance to promote current flow through to the second WSR layer 512. In one embodiment, the second WSR layer 512 has a high film conductivity and low refractive index for high film reflectance, while having low contact resistance to the second TCO layer 122. Accordingly, it is desirable to form a second WSR layer 512 that has a low contact resistance to its adjacent layers and low refractive index as well as a high reflectance. In the embodiment the second WSR layer 512 comprises a carbon doped n-type silicon alloy layer (SiC), since SIC layers typically have a higher conductivity as compared to an n-type silicon oxynitride (SiON) layer. In some cases, the first WSR layer 112 or the second WSR layer 512 is formed from an n-type SiON layer, since n-type SiON layers typically have a lower refractive index than an n-type SiC layers.

In one embodiment, the first WSR layer 112 is desired to have a refractive index between about 1.4 and about 4, such as about 2, while the second WSR layer 512 is desired to have a refractive index between about 1.4 and about 4, such as about 2. The first WSR layer 112 is desired to have conductivity between about greater 10⁻⁹ S/cm and the second WSR layer 112 is desired to have conductivity about greater than 10⁻⁴ S/cm.

Similar to the first p-i-n junction 126 depicted in FIG. 1, the first p-i-n junction 508 includes the p-type amorphous silicon layer 106, the intrinsic type amorphous silicon layer 108 and the n-type microcrystalline silicon layer 110. Similar to the structure depicted in FIGS. 2 and 3, a degeneratively-doped p-type amorphous silicon layer 502 (a heavily doped p-type amorphous silicon layer) is formed over the conductive layer 104. Furthermore, an n-type amorphous silicon buffer layer 504 is formed between the intrinsic type amorphous silicon layer 108 and the n-type microcrystalline silicon layer 110. The n-type amorphous silicon buffer layer 504 is formed to a thickness between about 10 Å and about 200 Å. It is believed that the n-type amorphous silicon buffer layer 504 helps bridge the bandgap offset that is believed to exist between the intrinsic type amorphous silicon layer 108 and the n-type microcrystalline silicon layer 110. Thus it is believed that cell efficiency is improved due to enhanced current collection, due to the addition of the n-type amorphous silicon buffer layer 504.

The second p-i-n junction 510, which is similar to the second p-i-n junction 128 of FIG. 1, comprises a p-type microcrystalline silicon layer 114, and an optional p-i buffer type intrinsic amorphous silicon (PIB) layer 116 that may be formed over the p-type microcrystalline silicon layer 114. Generally, the intrinsic type microcrystalline silicon layer 118 is formed over optional p-i buffer type intrinsic amorphous silicon (PIB) layer 116, and the n-type amorphous silicon layer 120 is formed over the intrinsic type microcrystalline silicon layer 118. Furthermore, a degeneratively-doped n-type amorphous silicon layer 406 may be formed primary as the heavily doped n-type amorphous silicon layer to provide improved ohmic contact with the second TCO layer 122. In one embodiment, the heavily doped n-type amorphous silicon layer 406 has a dopant concentration between about 10²⁰ atoms per cubic centimeter and about 10²¹ atoms per cubic centimeter.

FIG. 5B depicts a cross sectional view of the first WSR layer 112 and the second WSR layer 512 formed in the tandem-junction thin-film solar cell 500 according to another embodiment of the invention. In one embodiment, the first WSR layer 112 and the second WSR layer 512 may each be formed from a plurality of deposited layers, such as layers 112a, 112b and layers 512a, 512b, to tailor the reflection and/or transmission of different wavelengths of light to different parts of the formed solar cell 500. For example, the layers 112a-b in the first WSR layer 112 may each have a different refractive index to effectively reflect one or more desired wavelengths of light (e.g., short to mid wavelengths) and transmit other wavelengths (e.g., mid to long wavelengths). The wavelengths transmitted through the layers 112a-b can subsequently be reflected back to the second p-i-n junction 510 by the second WSR layer 512. By selectively adjusting the refractive index in each of the plurality of layers found in the WSR layers 112, 512 can each be tailored to selectively reflect or transmit light at different wavelengths, so as to maximize the absorption of the incident light in desirable regions of the solar cell to improve current generation and the solar cell efficiency. While FIG. 5B illustrates a configuration where the WSR layers 112 and 512 each comprise two layers, this configuration is not intended to be limiting as to the scope of the invention described herein, and is generally intended to only illustrate a configuration in which the WSR layers comprise two or more stacked layers. FIG. 6A illustrates one configuration of two or more stacked layers and is further discusses below.

In one embodiment, each adjacent layer within the layers 112a-b, 512a-b are configured to have high refractive index contrast and differing thickness. A high refractive index contrast and differing thickness of the layers contained in the layers 112a-b, 512a-b can assist in the tuning of the optical properties of the formed layers 112a-b, 512a-b. In one embodiment, the layers 112a-b and 512a-b are configured to also have a high refractive index contrast with the layers that they are positioned adjacent to, such as the n-type layer 110, p-type layer 114 and second TCO layer 122, respectively. In general, the term refractive index contrast is intended to describe the degree of difference in the refractive index of adjacent layers, which is typically denoted as a ratio of the index of refractions. Thus, a low refractive index contrast means that there is only a small difference in the refractive index between the adjacent layers and a high refractive index contrast is where there is a large difference in the refractive index of the adjacent materials. In one example, the optical properties of the layers 112a-b and layers 512a-b are configured to reflect and transmit different wavelengths of light. In one embodiment, the layers 112a-b, 512a-b are configured to reflect light at wavelength at between about 550 nm and about 1100 nm. In one embodiment, the first WSR layer 112 is configured to reflect light at wavelengths between about 550 nm and about 800 nm, while the second WSR layer 512 is configured to reflect light at wavelengths between about 700 nm and about 1100 nm. In one embodiment, the first layer 112a is configured to have a lower refractive index, and the second layer 112b is configured to have higher refractive index. For example, material of the first layer 112a is selected to have a lower refractive index (e.g., SiC, SiO_{x, Si}ₓO_{y}N_{z}) than the material selected for the second layer 112b (e.g., Si). The thickness of the first layer 112a is configured to have a thicker thickness to the second layer 112b. In one embodiment, the refractive index ratio of the second layer 112b to the first layer 112a (refractive index of the second layer/refractive index of the first layer) is controlled greater than about 1.2, such as greater than about 1.5. In one embodiment, the first layer 112a has a refractive index between about 1.4 and about 2.5 and the second layer 112b has a refractive index between about 3 and about 4. The thickness ratio of the first layer 112a to the second layer 112b (thickness of the first layer/thickness of the second layer) is controlled greater than about 1.2, such as greater than about 1.5.

In one embodiment, the first layer 112a is an n-type microcrystalline silicon alloy layer having a thickness between about 75 Å and about 750 Å and the second layer 112b is a n-type microcrystalline silicon layer having a thickness between about 50 Å and about 500 Å. However, varying the optical properties of the WSR layer can also be done by others techniques (i.e., other than varying the thicknesses of alternating the first layer 112a and the second layer 112b to be λ/4n(Si) and λ/4n(Si-alloy), respectively), since periodic structures that have high reflectivity and acceptable absorption loss can be formed by forming a first layer 112a and a second layer 112b, or a series of repeating first and second layers, that have a discontinuity in the refractive index at their interfaces which is used to alter the optical properties of the WSR layer structure as a whole. In one embodiment, the first layer 112a is an n-type microcrystalline silicon alloy layer, such as SiC or SiON layer, having a thickness about 450 Å and the second layer 112b is an n-type microcrystalline silicon layer having a thickness about 300 Å. Similarly, the second WSR layer 512 may be similarly configured to have high refractive index contrast and differing thickness between the first layer 512a and the second layer 512b. It is contemplated that the second WSR layer 512 may be similarly configured like the first WSR layer 112, so the description of the second WSR layer 512 is not further discussed here for sake of brevity.

FIG. 5B only depicts a pair of two layers, such as the first layer 112a and the second layer 112b. It is noted that the pair of the first layer 112a and the second layer 112b may be repeatedly formed a number of times to form the first a multilayer stack that forms the WSR layer 112, as shown in FIG. 6A. In one embodiment, the first WSR layer 112 may comprise multiple pairs of the first layer 112a1, 112a2, 112a3 and the second layer 112b1, 112b2, 112b3. In one embodiment, as illustrated in FIG. 6A, three pairs of the first and the second layers are shown. Each of the formed first and the second layer 112a1-3, 112b1-3 in the pairs may have a different refractive index and a different thickness. For example, the first pair of the layers 112a1, 112b1 may have a refractive index ratio of the second layer 112b1 to the first layer 112a1 greater than about 1.2, such as greater than about 1.5. In contrast, the first pair of the layers 112a1, 112b1 may have a thickness ratio of the first layer 112a1 to the second layer 112b1 greater than about 1.2, such as greater than about 1.5. The second pair of the layers 112a2, 112b2 may have a higher or lower refractive index ratio, as compared to the first pair 112a1, 112b1, to assist in the reflection of light by the first WSR layer 112. Furthermore, the third pair of the layers 112a3, 112b3 may have an even higher or lower refractive index contrast, as compared to the first pair 112a1, 112b1 and the second pair 112a2, 112b2.

In one embodiment, the first WSR layer 112 may have three pairs of layers 112a, 112b formed therein. In another embodiment, the first WSR layer 112 may have up to five pairs of the layers 112a, 112b. In yet another embodiment, the first WSR layer 112 may have greater than five pairs of the layers 112a, 112b as needed. Alternatively, the first pair 112a1, 112b1, the second pair 112a2, 112b2, and the third pair 112a3, 112b3 may comprise repeated pairs of layers having similar refractive index contrast and thickness variation in each pair. The reflectance for a given wavelength can be optimized by adjusting the period and ratio of refractive index, thereby producing desired wavelength-selective reflectors.

In one embodiment, the first layer 112a1 in the first pair of layers may have a refractive index of about 2.5 and a thickness of about 150 Å and the second layer 112b1 has a refractive index of about 3.8 and a thickness of about 100 Å. The second layer 112a2 in the second pair of layers may have a refractive index of about 2.5 and a thickness of about 150 Å, and the second layer 112b2 in the second pair of layers has a refractive index of about 3.8 and a thickness of about 100 Å. The third layer 112a3 of the third pair of layers may have a refractive index of about 2.5 and a thickness of about 150 Å and the second layer 112b2 of the third pair of layers has a refractive index of about 3.8 and a thickness of about 100 Å. In one example, the total thickness of the first WSR layer 112 is controlled at about 750 Å.

FIG. 6B depicts another configuration of the WSR layer 112 that may be used to improve light reflection, current collection and light transmission. In this particular embodiment, the WSR layer 112 comprises one or more insulating layers, such as the multiple layers described in FIG. 6B, that have a low refractive index, such as Si, SiO₂, SiON, SiN or the like. It is believed that dopants or alloying elements that are used to form the WSR layer 112 may improve film conductivity, but may adversely increase absorption loss, which may reduce light reflectance and transmittance between the different junctions in the formed solar cell. Accordingly, in one embodiment, it is desirable to form an array of apertures 602, or features or regions, in the WSR layer 112 that allow a subsequently deposited layer (e.g., reference numeral 114), which has a higher conductivity, to form a series of shunt paths 602A through WSR layer 112 that can carry a significant portion of the generated current. The WSR layer 112 and series of formed shunt paths 602A are thus used in combination to leverage the desirable optical properties of the WSR layer 112, while also having a reduced series resistance across the WSR layer (e.g., across the layer thickness) by use of the formed shunt paths 602A. This configuration may be useful in case where the WSR layer 112 comprises one or more highly resistive layers or dielectric materials, which are primarily needed for their optical properties (e.g., reflective and/or transmissive properties).

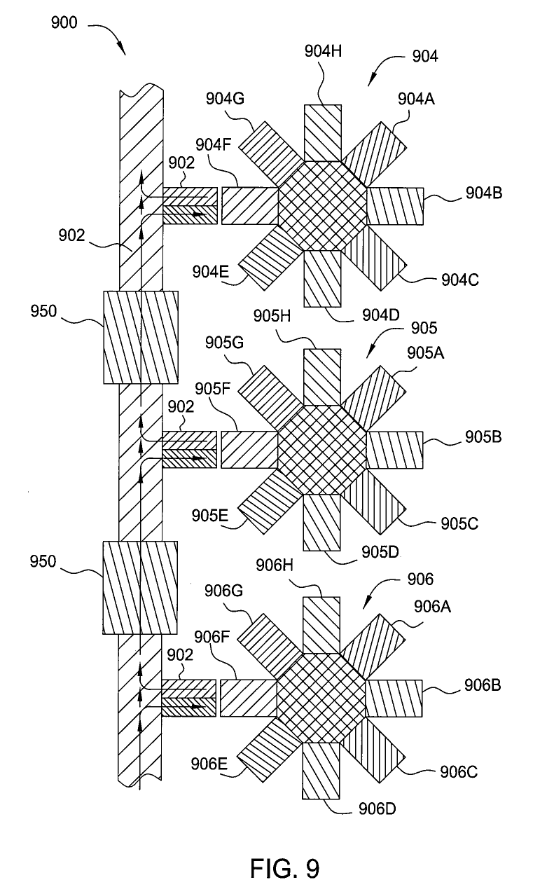

In one example, the WSR layer contains an insulating layer having low refractive index, such as lower than 2. Subsequently, the insulating WSR layer 112 is patterned to form an array of holes, trenches, slots or other shaped opening within the insulating WSR layer 112. In general, the array of apertures 602 will have a sufficient density and size (e.g., diameter) to reduce the average resistance across the WSR layer 112 to a desirable level, while assuring that the WSR layer retains its desirable optical properties. More details regarding the patterning process and suitable pattering chambers that may be utilized to perform the patterning process are described below with reference to FIG. 9. In one example, the apertures 602 are filled with the p-type microcrystalline silicon layer 114 that is disposed over the more insulating WSR layer 112 to form the shunt paths 602A. In this configuration, by selecting the WSR layer 112 that has a lower refractive index the optical properties of one or more layers within the WSR layer 112 may be obtained. While by filling the formed apertures with p-type microcrystalline silicon layer 114, the average resistance across the formed WSR layer 112 can be reduced, thus improving the average optical properties and average electrical properties of the patterned WSR layer 112 and the efficiency of the formed solar cell device. In one embodiment, the insulating WSR layer 112 is a silicon oxide layer having p-type microcrystalline silicon layer 114 formed therein.

The tandem and/or, in some embodiment, triple junction embodiments, contemplate variations available in the type of alloy materials included in the various layers. For example, in one embodiment, the layers of one p-i-n junction may use carbon as an alloy material, while the layers of another p-i-n junction comprise a germanium containing material. For example, in the embodiment of FIGS. 1, 5A-B, the crystalline alloy WSR layer 112 may comprise an alloy of silicon and carbon, while the layers of the first and the second p-i-n junctions 126, 128 508, 510 may comprise an alloy of silicon and germanium, or vise versa. Finally, the embodiments of FIGS. 1 and 5A-B also contemplate variations wherein one of the intrinsic layers is not an alloy layer. For example, in an alternate embodiment of FIGS. 1 and 5A-B, the layers 108, 118 is an intrinsic microcrystalline silicon layer, not an alloy layer. Such variations broaden the absorption characteristics of the cell and improve its charge separation capabilities.

### EXAMPLES

A single junction solar cell constructed with a 280 Å microcrystalline silicon carbide n-layer exhibited short current (J_{sc}) of 13.6 milliAmps per square centimeter (mA/cm²) (such as 13.4 mA/cm² obtained from quantum efficiency (QE) measurements) and fill factor (FF) of 73.9%, with conversion efficiency (CE) of 9.4%. By comparison, a similar cell using microcrystalline silicon exhibited J_{sc} of 13.2 mA/cm² (such as 13.0 mA/cm² obtained from QE measurements), FF of 73.6%, and CE of 9.0%. By further comparison, a similar cell using a 280 Å amorphous silicon n-layer, 80 Å of which is degeneratively doped, exhibited J_{sc} of 13.1 mA (such as 12.7 mA/cm² obtained from QE measurements), FF of 74.7%, and CE of 9.0.

A tandem junction solar cell was constructed having a bottom cell n-layer comprising 270 Å of microcrystalline silicon carbide, and a top cell n-layer comprising 100 Å of an n-type amorphous silicon and 250 Å of an n-type microcrystalline silicon carbide. The bottom cell exhibited J_{sc} of 9.69 mA/cm² and QE of 58% at a wavelength of 700 nm. The top cell exhibited J_{sc} of 10.82 mA/cm² and QE of 78% at a wavelength of 500 nm. Another tandem solar cell was constructed having a bottom cell n-layer comprising 270 Å of an n-type microcrystalline silicon carbide, and a top cell n-layer comprising 50 Å of an n-type amorphous silicon, and 250 Å of an n-type microcrystalline silicon carbide. The bottom cell exhibited J_{sc} of 9.62 mA/cm² and QE of 58% at a wavelength of 700 nm. The top cell exhibited J_{sc} of 10.86 mA and QE of 78% at a wavelength of 500 nm. By comparison, a tandem junction solar cell was constructed having a bottom cell n-layer comprising 270 Å of n-type microcrystalline silicon, and a top cell n-layer comprising 200 Å of n-type amorphous silicon and 90 Å of degeneratively doped (n-type) amorphous silicon. The bottom cell exhibited J_{sc} of 9.00 mA/cm² and QE of 53% at a wavelength of 700 nm. The top cell exhibited J_{sc} of 10.69 mA/cm² and QE of 56% at a wavelength of 500 nm. Use of silicon carbide thus improved absorption in both cells, most notably in the bottom cell.

### System and Apparatus Configurations

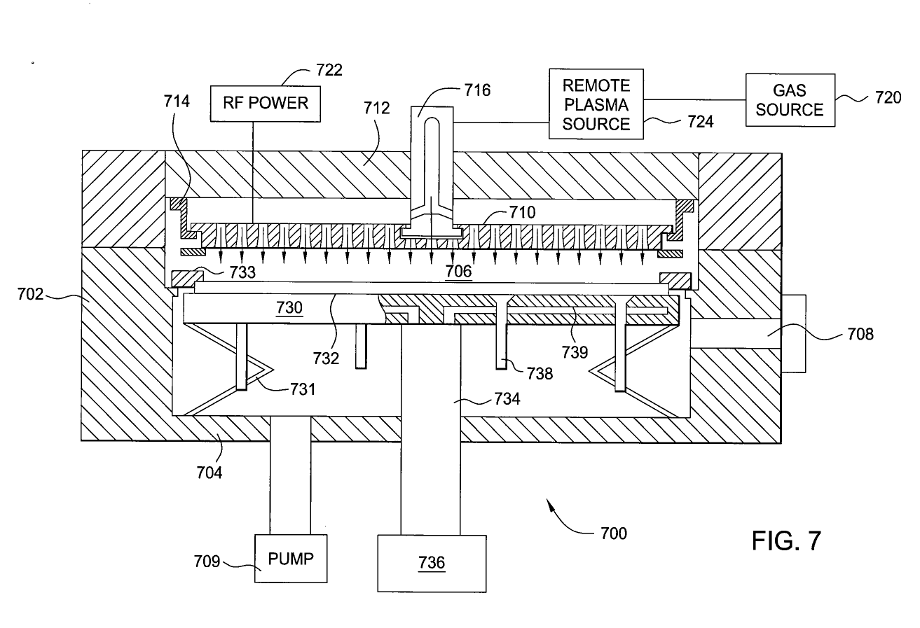

FIG. 7 is a schematic cross-section view of one embodiment of a plasma enhanced chemical vapor deposition (PECVD) chamber 700 in which one or more films of a thin-film solar cell, such as the solar cells of FIGS. 1-4 may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 700 generally includes walls 702, a bottom 704, and a showerhead 710, and substrate support 730 which define a process volume 706. The process volume is accessed through a valve 708 such that the substrate, may be transferred in and out of the chamber 700. The substrate support 730 includes a substrate receiving surface 732 for supporting a substrate and stem 734 coupled to a lift system 736 to raise and lower the substrate support 730. A shadow ring 733 may be optionally placed over periphery of the substrate 102. Lift pins 738 are moveably disposed through the substrate support 730 to move a substrate to and from the substrate receiving surface 732. The substrate support 730 may also include heating and/or cooling elements 739 to maintain the substrate support 730 at a desired temperature. The substrate support 730 may also include grounding straps 731 to provide RF grounding at the periphery of the substrate support 730.

The showerhead 710 is coupled to a backing plate 712 at its periphery by a suspension 714. The showerhead 710 may also be coupled to the backing plate by one or more center supports 716 to help prevent sag and/or control the straightness/curvature of the showerhead 710. A gas source 720 is coupled to the backing plate 712 to provide gas through the backing plate 712 and through the showerhead 710 to the substrate receiving surface 732. A vacuum pump 709 is coupled to the chamber 700 to control the process volume 706 at a desired pressure. An RF power source 722 is coupled to the backing plate 712 and/or to the showerhead 710 to provide a RF power to the showerhead 710 so that an electric field is created between the showerhead and the substrate support 730 so that a plasma may be generated from the gases between the showerhead 710 and the substrate support 730. Various RF frequencies may be used, such as a frequency between about 0.3 MHz and about 200 MHz. In one embodiment the RF power source is provided at a frequency of 13.56 MHz.

A remote plasma source 724, such as an inductively coupled remote plasma source, may also be coupled between the gas source and the backing plate. Between processing substrates, a cleaning gas may be provided to the remote plasma source 724 so that a remote plasma is generated and provided to clean chamber components. The cleaning gas may be further excited by the RF power source 722 provided to the showerhead. Suitable cleaning gases include but are not limited to NF₃, F₂, and SF₆.

The deposition methods for one or more layers, such as one or more of the layers of FIGS. 1-4, may include the following deposition parameters in the process chamber of FIG. 6 or other suitable chamber. A substrate having a surface area of 10,000 cm² or more, preferably 40,000 cm² or more, and more preferably 55,000 cm² or more is provided to the chamber. It is understood that after processing the substrate may be cut to form smaller solar cells.

In one embodiment, the heating and/or cooling elements 639 may be set to provide a substrate support temperature during deposition of about 400° C. or less, preferably between about 100° C. and about 400° C., more preferably between about 150° C. and about 300° C., such as about 200° C.

The spacing during deposition between the top surface of a substrate disposed on the substrate receiving surface 632 and the showerhead 610 may be between 400 mil and about 1,200 mil, preferably between 400 mil and about 800 mil.

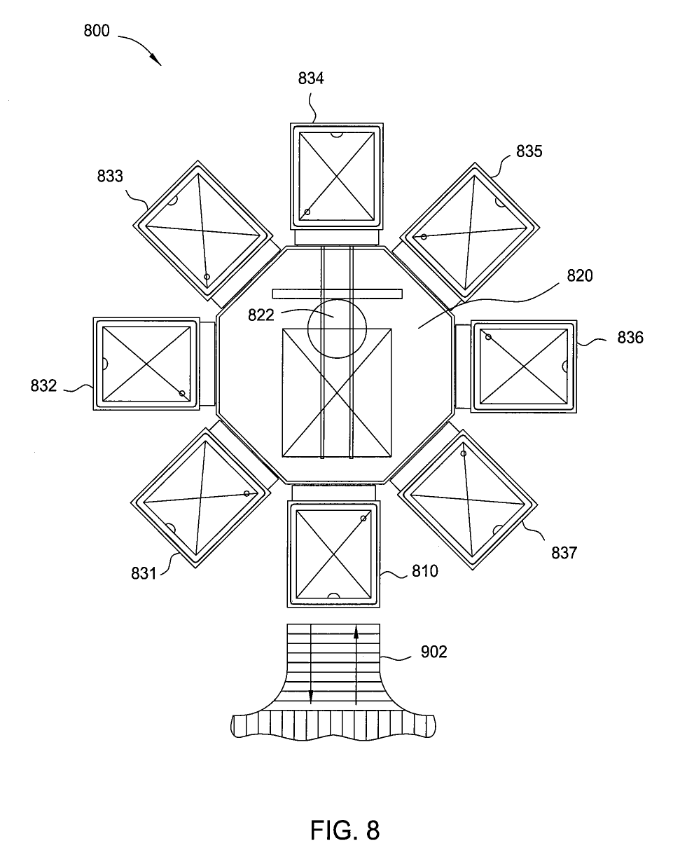

FIG. 8 is a top schematic view of one embodiment of a process system 800 having a plurality of process chambers 831-837, such as PECVD chamber 700 of FIG. 7 or other suitable chambers capable of depositing silicon films. The process system 800 includes a transfer chamber 820 coupled to a load lock chamber 810 and the process chambers 831-837. The load lock chamber 810 allows substrates to be transferred between the ambient environment outside the system and vacuum environment within the transfer chamber 820 and process chambers 831-837. The load lock chamber 810 includes one or more evacuatable regions holding one or more substrate. The evacuatable regions are pumped down during input of substrates into the system 800 and are vented during output of the substrates from the system 800. The transfer chamber 820 has at least one vacuum robot 822 disposed therein that is adapted to transfer substrates between the load lock chamber 810 and the process chambers 831-837. While seven process chambers are shown in FIG. 8; this configuration is not intended to be limiting as to the scope of the invention, since the system may have any suitable number of process chambers.

In certain embodiments of the invention, the system 800 is configured to deposit the first p-i-n junction (e.g., reference numeral 126, 328, 508) of a multi-junction solar cell. In one embodiment, one of the process chambers 831-837 is configured to deposit the p-type layer(s) of the first p-i-n junction while the remaining process chambers 831-837 are each configured to deposit both the intrinsic type layer(s) and the n-type layer(s). The intrinsic type layer(s) and the n-type layer(s) of the first p-i-n junction may be deposited in the same chamber without any passivation process in between the deposition steps. Thus, in one configuration, a substrate enters the system through the load lock chamber 810, the substrate is then transferred by the vacuum robot into the dedicated process chamber configured to deposit the p-type layer(s). Next, after forming the p-type layer the substrate is transferred by the vacuum robot into one of the remaining process chamber configured to deposit both the intrinsic type layer(s) and the n-type layer(s). After forming the intrinsic type layer(s) and the n-type layer(s) the substrate is transferred by the vacuum robot 822 back to the load lock chamber 810. In certain embodiments, the time to process a substrate with the process chamber to form the p-type layer(s) is approximately 4 or more times faster, preferably 6 or more times faster, than the time to form the intrinsic type layer(s) and the n-type layer(s) in a single chamber. Therefore, in certain embodiments of the system to deposit the first p-i-n junction, the ratio of p-chambers to i/n-chambers is 1:4 or more, preferably 1:6 or more. The throughput of the system including the time to provide plasma cleaning of the process chambers may be about 10 substrates/hr or more, preferably 20 substrates/hr or more.

In certain embodiments of the invention, a system 800 is configured to deposit the second p-i-n junction (e.g., reference numerals 128, 330, 510) of a multi-junction solar cell. In one embodiment, one of the process chambers 831-837 is configured to deposit the p-type layer(s) of the second p-i-n junction while the remaining process chambers 831-837 are each configured to deposit both the intrinsic type layer(s) and the n-type layer(s). The intrinsic type layer(s) and the n-type layer(s) of the second p-i-n junction may be deposited in the same chamber without any passivation process in between the deposition steps. In certain embodiments, the time to process a substrate with the process chamber to form the p-type layer(s) is approximately 4 or more times faster than the time to form the intrinsic type layer(s) and the n-type layer(s) in a single chamber. Therefore, in certain embodiments of the system to deposit the second p-i-n junction, the ratio of p-chambers to i/n-chambers is 1:4 or more, preferably 1:6 or more. The throughput of the system including the time to provide plasma cleaning of the process chambers may be about 3 substrates/hr or more, preferably 5 substrates/hr or more.

In certain embodiments of the invention, a system 800 is configured to deposit the WSR layer 112, 512, as depicted in FIGS. 1, 5A-B, that may be disposed between a first and a second p-i-n junction or a second p-i-n junction and a second TCO layer. In one embodiment, one of the process chambers 831-837 is configured to deposit one or more of the WSR layers, and another one of the process chambers 831-837 is configured to deposit the p-type layer(s) of the second p-i-n junction while the remaining process chambers 831-837 are each configured to deposit both the intrinsic type layer(s) and the n-type layer(s). The number of the chambers configured to deposit the WSR layer may be similar to the number of the chambers configured to deposit the p-type layer(s). Additionally, the WSR layer may be deposited in the same chamber configured to deposit both the intrinsic type layer(s) and the n-type layer(s).

In certain embodiments, the throughput of a system 800 that is configured for depositing the first p-i-n junction comprising an intrinsic type amorphous silicon layer has a throughput that is two times larger than the throughput of a system 800 that is used to deposit the second p-i-n junction comprising an intrinsic type microcrystalline silicon layer, due to the difference in thickness between the intrinsic type microcrystalline silicon layer(s) and the intrinsic type amorphous silicon layer(s). Therefore, a single system 800 that is adapted to deposit the first p-i-n junction, which comprises an intrinsic type amorphous silicon layer, can be matched with two or more systems 800 that are adapted to deposit a second p-i-n junction, which comprises an intrinsic type microcrystalline silicon layer. Accordingly, the WSR layer deposition process may be configured to be performed in the system adapted to deposit the first p-i-n junction for efficient throughput control. Once a first p-i-n junction has been formed in one system, the substrate may be exposed to the ambient environment (i.e., vacuum break) and transferred to the second system, where the second p-i-n junction is formed. A wet or dry cleaning of the substrate between the first system depositing the first p-i-n junction and the second p-i-n junction may be necessary. In one embodiment, the WSR layer deposition process may be configured to deposit in a separate system.

FIG. 9 illustrates one configuration of a portion of a production line 900 that has a plurality of deposition systems 904, 905, 906, or cluster tools, that are transferrably connected by automation devices 902. In one configuration, as shown in FIG. 9, the production line 900 comprises a plurality of deposition systems 904, 905, 906 that may be utilized to form one or more layers, form p-i-n junction(s), or form a complete solar cell device on a substrate 102. The systems 904, 905, 906 may be similar to the system 800 depicted in FIG. 8, but are generally configured to deposit different layer(s) or junction(s) on the substrate 102. In general, each of the deposition systems 904, 905, 906 each have a load lock 904F, 905F, 906F, which is similar to the load lock 810, that are each in transferable communication with an automation device 902.

During process sequencing, a substrate is generally transported from a system automation device 902 to one of the systems 904, 905, 906. In one embodiment, the system 906 has a plurality of chambers 906A-906H that are each configured to deposit or process one or more layers in the formation of a first p-i-n junction, the system 905 having a plurality of chambers 905A-905H is configured to deposit the one or more WSR layer(s), and the system 904 having the plurality of chambers 904A-904H is configure to deposit or process one or more layers in the formation of a second p-i-n junction. It is noted that the number of systems and the number of the chambers configured to deposit each layer in each of the systems may be varied to meet different process requirements and configurations. In one embodiment, it is desirable to separate or isolate the WSR layer deposition process chambers from the p-type, intrinsic or n-type layer deposition chambers to prevent the cross contamination of one or more of the layers in the formed solar cell device or subsequently formed solar cell devices. In configurations where the WSR layer comprises a carbon or an oxygen containing layer, it is generally important to prevent the cross contamination of the formed intrinsic layer(s) in the formed junctions, and/or prevent particle generation problems due to the stress in the oxygen or carbon containing deposited material layers formed on the shields or other chamber components in a processing chamber.

The automation device 902 may generally comprise a robotic device or conveyor that is adapted to move and position a substrate. In one example, the automation device 902 is a series of conventional substrate conveyors (e.g., roller type conveyor) and/or robotic devices (e.g., 6-axis robot, SCARA robot) that are configured to move and position the substrate within the production line 900 as desired. In one embodiment, one or more of the automation devices 902 also contains one or more substrate lifting components, or drawbridge conveyors, that are used to allow substrates upstream of a desired system to be delivered past a substrate that would be blocking its movement to another desired position within the production line 900. In this way the movement of substrates to the various systems will not be impeded by other substrates waiting to be delivered to another system.

In one embodiment of the production line 900, a patterning chamber 950 is in communication with one or more of the conveyors 902, and is configured to perform a patterning process on one or more of the layers in the formed WSR layer. In one example, the patterning chamber 950 is advantageously positioned to perform a patterning process on one or more of the layers in the WSR layer by conventional means. The patterning process may be used to form the patterned regions in the WSR layer, such as the trenches 602 formed in the insulating WSR layer 112 as depicted in FIG. 6B. It is also contemplated that the patterning process can also be used to etch one or more regions in one or more of the previously formed layers during the solar cell devices formation process. Typical processes that may be used to form the patterned regions 602 may include but are not limited to lithographic patterning and dry etching techniques, laser ablation techniques, patterning and wet etching techniques, or other similar processes that may be used to form a desired pattern in the WSR layer 112. The array of patterned regions 602 formed in the WSR layer 112 generally provide regions through which electrical connections can be made between the layers formed above the WSR layer 112 and the layers formed below the WSR layer 112.

While the configurations of the patterning chamber 950 generally discuss etching type patterning processes, this configuration need not be limiting as to the scope of the invention described herein. In one embodiment, the patterning chamber 950 is used to remove one or more regions in one or more of the formed layers and/or deposit one or more material layers (e.g., dopant containing materials, metals pastes) on the one or more of the formed layers on the substrate surface.

In one embodiment, the patterned regions 602 are etched into the WSR layer 112 by use of a deposited pattern etching process. The deposited pattern etching process generally starts by first depositing an etchant material in a desired pattern on a surface of the substrate 102 to match a desired configuration of patterned regions 602 that are to be formed in the WSR layer 112. In one embodiment, the etchant material is selectively deposited on the WSR layer 112 in the patterning chamber 950 by use of a conventional ink jet printing device, rubber stamping device, screen printing device, or other similar process. In one embodiment, the etchant material comprises ammonium fluoride (NH₄F), a solvent that forms a homogeneous mixture with ammonium fluoride, a pH adjusting agent (e.g., BOE, HF), and a surfactant/wetting agent. In one example, the etchant material comprises 20 g of ammonium fluoride that is mixed together with 5 ml of dimethylamine, and 25 g of glycerin, which is then heated to 100° C. until the pH of the mixture reaches about 7 and a homogeneous mixture is formed. It is believed that one benefit of using an alkaline chemistry is that no volatile HF vapors will be generated until the subsequent heating process(es) begins to drive out the ammonia (NH₃), thus reducing the need for expensive and complex ventilation and handling schemes prior to performing the heating process(es).

After depositing the etchant material in a desired pattern, the substrate is then heated in the patterning chamber 950 using conventional IR heating elements or IR lamps to a temperature of between about 200-300° C. to cause the chemicals in the etchant material to etch the WSR layer 112 to form the patterned regions 602. The patterned regions 602 provide openings in the WSR layer 112, as depicted in FIG. 6B, through which contact can be made between the layers formed below the WSR layer 112 and the layers deposited over the WSR layer 112. In one embodiment the patterned regions 602 on the surface of the substrate are between about 5 μm and about 2000 μm in diameter. Therefore, after processing for a desired period of time (e.g., ˜2 minutes) at a desired temperature the volatile etch products will be removed and a clean surface is left within the patterned regions 602 so that a reliable electrical contact can be formed in these areas. One desirable aspect of the process sequence and etchant formulations discussed herein is the ability to form the patterned regions 602 in the WSR layer 112 without the need to perform any post cleaning processes due to the removal of the etching products and residual etchant material by evaporation, thus leaving a clean surface that can have the second p-i-n junctions 510, 128 formed thereon. In some cases it is desirable to avoid performing wet processing steps to avoid the added time required to rinse and dry the substrate, the increase in cost-of-ownership associated with performing wet processing steps, and the added chance of oxidizing or contaminating the patterned regions 602. However, in one embodiment, the patterning chamber 950, or other attached processing chamber, is adapted to perform an optional cleaning process on the substrate to remove any undesirable residue and/or form a passivated surface before the second p-i-n junctions 510, 128 formed thereon. In one embodiment, the clean process may be performed by wetting the substrate with a cleaning solution. Wetting may be accomplished by spraying, flooding, immersing of other suitable technique. An example of a deposited pattern etching material process that can be used to form one or more of the patterned regions 602 is further discussed in the commonly assigned and copending U.S. patent application Ser. Nos. 12/274,023 [Atty. Docket #: APPM 12974.02], filed Nov. 19, 2008, which is herein incorporated by reference in its entirety.

While the foregoing is directed to embodiments of the present invention, other and further embodiments of the invention may be devised without departing from the basic scope thereof, and the scope thereof is determined by the claims that follow. For example, the process chamber of FIG. 7 has been shown in a horizontal position. It is understood that in other embodiments of the invention the process chamber may be in any non-horizontal position, such as vertical. Embodiments of the invention have been described in reference to the multi-process chamber cluster tool in FIGS. 8 and 9, but in-line systems and hybrid in-line/cluster systems may also be used. Embodiments of the invention have been described in reference to a first system configured to form a first p-i-n junction and a second system configured to form an WSR layer and a third system configured to form a second p-i-n junction, but the first p-i-n junction, WSR layer and a second p-i-n junction may also be formed in a single system. Embodiments of the invention have been described in reference to a process chamber adapted to deposit both an WSR layer, an intrinsic type layer and a n-type layer, but separate chambers may be adapted to deposit the intrinsic type layer and the n-type layer and an WSR layer and a single process chamber may be adapted to deposit both a p-type layer, a WSR layer and an intrinsic type layer. Finally, the embodiments described herein are p-i-n configurations generally applicable to transparent substrates, such as glass, but other embodiments are contemplated in which n-i-p junctions, single or multiply stacked, are constructed on opaque substrates such as stainless steel or polymer in a reverse deposition sequence.

Thus, an apparatus and methods for forming a WSR layer in a solar cell device are provided. The method advantageously produces a WSR layer disposed between junctions that pertains high transparency and low refractive index to enhance light trapping in the cells. Additionally, the WSR layer also provides adjustable bandgap that can efficiently reflect or absorb light in different wavelengths, thereby increasing the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. A photovoltaic device, comprising:
a reflector layer disposed between a first p-i-n junction and a second p-i-n junction, wherein the reflector layer comprises:
a first layer; and
a second layer disposed over the first layer, wherein the refractive index ratio of the second layer to the first layer is greater than about 1.2.

2. The photovoltaic device of claim 1, wherein
the first p-i-n junction comprises:
a p-type amorphous silicon layer;
an intrinsic type amorphous silicon layer; and
an n-type microcrystalline silicon layer; and
the second p-i-n junction comprises:
a p-doped microcrystalline silicon layer disposed on the second layer;
an intrinsic type microcrystalline silicon layer; and
an n-doped amorphous silicon layer adjacent to the intrinsic type microcrystalline silicon layer.

3. The photovoltaic device of claim 1, wherein the thickness ratio of the first layer to the second layer is greater than about 1.2.

4. The photovoltaic device of claim 1, further comprising:
a second pair layers that comprise:
a third layer disposed on the second layer, wherein the refractive index ratio of the second layer to the third layer is greater than about 1.2; and
a fourth layer disposed over the third layer, wherein the refractive index ratio of the fourth layer to the third layer is greater than about 1.2; and
a third pair layers that comprise:
a fifth layer disposed on the fourth layer, wherein the refractive index ratio of the fourth layer to the fifth layer is greater than about 1.2; and
a sixth layer disposed over the fifth layer, wherein the refractive index ratio of the sixth layer to the fifth layer is greater than about 1.2.

5. The photovoltaic device of claim 1, wherein the second layer has a refractive index higher than the first layer.

6. The photovoltaic device of claim 1, wherein the reflector layer selectively reflects light at wavelength between about 550 nm and about 800 mm.

7. The photovoltaic device of claim 1, wherein the first layer is an n-type microcrystalline silicon alloy layer.

8. The photovoltaic device of claim 1, wherein the second layer is an n-type microcrystalline silicon layer.

9. The photovoltaic device of claim 1, wherein the first layer comprises silicon, oxygen and an element selected from a group consisting of nitrogen and carbon.

10. The photovoltaic device of claim 1, wherein the first layer has a refractive index between about 1.4 and about 2.5 and the second layer has a refractive index between about 3 and about 4.

11. A photovoltaic device, comprising:
a reflector layer disposed between a first p-i-n junction and a second p-i-n junction, and having a plurality of apertures formed therein, wherein each of the plurality of apertures are formed by removing a portion of material from the reflector layer before the second p-i-n junction is formed over the reflector layer.

12. The photovoltaic device of claim 11, wherein at least a portion of the second p-i-n junction fills at least a portion of each of the formed plurality of apertures.

13. The photovoltaic device of claim 11, wherein
the first p-i-n junction comprises:
a p-type amorphous silicon layer;
an intrinsic type amorphous silicon layer; and
an n-type microcrystalline silicon layer; and
the second p-i-n junction comprises:
a p-doped microcrystalline silicon layer disposed on the reflector layer;
an intrinsic type microcrystalline silicon layer; and
an n-doped amorphous silicon layer adjacent to the intrinsic type microcrystalline silicon layer.

14. The photovoltaic device of claim 11, wherein the reflector layer comprises silicon, oxygen, and an element selected from a group consisting of nitrogen and carbon.

15. The photovoltaic device of claim 11, wherein the reflector layer comprises a first layer, and a second layer disposed over the first layer, wherein the refractive index ratio of the second layer to the first layer is greater than about 1.2.

16. A method of forming a solar cell device, comprising:
forming a first p-i-n junction on a surface of a substrate;
forming an first reflector layer over the first p-i-n junction, wherein the first reflector layer selectively reflects light having a wavelength between about 550 nm and about 800 nm back to the first p-i-n junction; and
forming a second p-i-n junction on the first reflector layer.

17. The method of claim 16, further comprising:
forming a second reflector layer over the second p-i-n junction; and
forming a transparent conductive layer over the second reflector layer.

18. The method of claim 17, wherein the second reflector layer reflects light at wavelength between about 700 nm and about 1100 nm back to the second p-i-n junction.

19. The method of claim 16, wherein the first reflector layer comprises an n-type microcrystalline silicon alloy.

20. The method of claim 16, wherein the first reflector layer has a refractive index between about 1.4 and about 4.

21. The method of 16, wherein forming the first reflector layer further comprises forming a first layer and a second layer on the first p-i-n junction, wherein the refractive index ratio of the second layer to the first layer is greater than 1.2.

22. The method of claim 21, wherein the first layer is a n-type microcrystalline silicon alloy layer and the second layer comprises an n-type microcrystalline silicon layer.

23. The method of claim 21, further comprising:
forming a second pair of the first and the second layer on the first pair; and
forming a third pair of the first and the second layer on the second pair.

24. The method of claim 16, wherein
forming the first p-i-n junction, comprises:
forming a p-type amorphous silicon layer;
forming an intrinsic type amorphous silicon layer over the p-type amorphous silicon layer, wherein the intrinsic type amorphous silicon layer includes a p-i buffer intrinsic type amorphous silicon layer and a bulk intrinsic type amorphous silicon layer; and
forming a n-type microcrystalline silicon layer over the intrinsic type amorphous silicon layer; and
forming the second p-i-n junction, comprises:
forming a p-type microcrystalline silicon layer on the reflector layer;
forming an intrinsic type microcrystalline silicon layer over the p-type microcrystalline silicon layer; and
forming an n-type amorphous silicon layer over the intrinsic type microcrystalline layer.

25. The method of claim 16, further comprising forming a plurality of apertures in the reflector layer, wherein the plurality of apertures are formed before the second p-i-n junction is formed over the reflector layer, and each aperture is formed by removing a portion of the reflector layer.

26. An automated and integrated system for forming a solar cell, comprising:
a first deposition chamber that is adapted to deposit a p-type silicon-containing layer on a surface of a substrate;
a second deposition chamber that is adapted to deposit an intrinsic type silicon-containing layer and an n-type silicon-containing layer on the surface of the substrate;
a third deposition chamber that is adapted to deposit an n-type reflector layer on the surface of the substrate;
a patterning chamber that is adapted to form a plurality of apertures in the n-type reflector layer on the surface of the substrate; and
an automated conveyor device that is adapted to transfer the substrate between the first deposition chamber, second deposition chamber, third deposition chamber and patterning chamber.

27. An automated and integrated system for forming a solar cell, comprising:
a first cluster tool comprising:
at least one processing chamber that is adapted to deposit a p-type silicon-containing layer on a surface of a substrate;
at least one processing chamber that is adapted to deposit a intrinsic type silicon-containing layer over the surface of the substrate; and
at least one processing chamber that is adapted to deposit a intrinsic type silicon-containing layer over the surface of the substrate; and
a second cluster tool comprising:
at least one processing chamber that is adapted to deposit an n-type reflector layer on a surface of the substrate; and
an automated conveyor device that is adapted to transfer a substrate between the first and second cluster tools.

28. The automated and integrated system of claim 27, further comprising:
a third cluster tool comprising:
at least one processing chamber that is adapted to deposit a p-type silicon-containing layer on the surface of the substrate;
at least one processing chamber that is adapted to deposit a intrinsic type silicon-containing layer over the surface of the substrate; and
at least one processing chamber that is adapted to deposit a intrinsic type silicon-containing layer over the surface of the substrate.

29. The automated and integrated system of claim 28, further comprising:
a patterning chamber that is in transferable communication with the first, second or third cluster tools and the automated conveyor device, wherein the patterning chamber is adapted to remove a portion of the n-type reflector layer to form a plurality of apertures in the n-type reflector layer.
